(19) United States
(12) Patent Application Publication
(10) Pub. No.: US 2005/0077587 A1
(43) Pub. Date: Apr. 14, 2005

(54) Monolithic semiconductor photo-coupler incorporating an optical fiber alignment groove

(76) Inventors: David Rolston, Pierrefonds (CA); Richard Benoit, Longueuil Quebec (CA); Thomas Maj, Montreal (CA)

Correspondence Address: HARRINGTON & SMITH, LLP, 4 RESEARCH DRIVE, SHELTON, CT, 06484-6212, US

(21) Appl. No.: 10/380,231

(22) PCT Filed: Sep. 10, 2002
(86) PCT No.: PCT/CA01/01269

(51) Int. Cl. H01L 31/0232

(52) U.S. Cl. 257/432

(57) ABSTRACT

A monolithic semiconductor photo-coupler device comprises a substrate made of semiconductor material, and a groove made in one face of the substrate to receive and align an optical fiber. A wall of given thickness is formed in the semiconductor material of the substrate in the prolongation of the groove and transversally to this groove. The wall has, on the side of the groove, a first face generally perpendicular to the groove, and a second face opposite to the first face. The semiconductor material preferably comprises silicon whereby p-doped and n-doped regions can be produced on the first and second faces of the wall, respectively. These p- and n-doped regions are separated by an intrinsic semiconductor region. Finally, first and second electrodes are applied to the substrate in contact with the p- and n-doped regions. The p-doped region, the intrinsic semiconductor region and the n-doped region form a p-i-n photodetector capable of converting an optical signal from an optical fiber placed in the groove to an electric signal. When placed in the groove, the optical fiber is in direct alignment with the photodetector. The present invention is also concerned with a method for fabricating the above described monolithic semiconductor photo-coupler device.

### BACKGROUND OF THE INVENTION

1. Field of the Invention

The present invention relates to a monolithic semiconductor photo-coupler device provided for direct alignment of an optical fiber with a photo-component.

2. Brief Description of the Prior Art

In the prior art, V-shaped grooves have been currently used to receive and align optical fibers with photo-components. Examples are described in the following prior art patent documents:

| | | |
|---|---|---|
| U.S. Pat. No. 5 355 386 | (Rothman et al.) | Oct. 11, 1994 |
| U.S. Pat. No. 5 389 193 | (Coucoulas et al.) | Feb. 14, 1995 |
| GB 2 334 788 A | (Ojha et al.) | Sep. 1, 1999 |
| EP 0 984 533 A2 | (Yamauchi) | Mar. 8, 2000. |

More specifically, Document GB 2 334 788 A describes a method by which V-shaped grooves etched in a substrate are aligned with a planar waveguide core deposited on the substrate.

Document U.S. Pat. No. 5,389,193 describes a method of bonding an optical fiber in a silicon V-shaped groove simply by applying heat and pressure. This avoids the use of any potentially contaminating adhesives.

Finally, Document U.S. Pat. No. 5,355,386 describes a monolithically integrated laser, detector and fiber-receiving channel. The fiber-receiving channel comprises a V-shaped groove etched through a wafer structure. The laser and detector are formed of a complex layered structure.

### OBJECT OF THE INVENTION

An object of the present invention is therefore to provide a simple structure and process of manufacture for a monolithic semiconductor photo-coupler device, in which a groove and photo-component are designed for direct alignment of an optical fiber with this photo-component.

### SUMMARY OF THE INVENTION

More specifically, in accordance with the present invention, there is provided a monolithic semiconductor photo-coupler device, comprising a substrate, a groove, a wall of given thickness, and first and second semiconductor regions. The substrate is made of semiconductor material, and the groove is made in one face of the substrate to receive and align an optical fiber. The wall is formed in the semiconductor material of the substrate in the prolongation of the groove and transversally to the groove. Also, this wall comprises, on the side of the groove, a first face generally perpendicular to the groove, and a second face opposite to the first face. The first and second semiconductor regions have different electrical properties and are formed in the semiconductor material on the first and second faces of the wall, respectively.

In this manner, installation of an optical fiber in the groove automatically positions this optical fiber in direct alignment with a photo-component including the first and second semiconductor regions.

In accordance with preferred embodiments of the monolithic semiconductor photo-coupler device according to the present invention:
the first semiconductor region is a doped region of a first type, and the second semiconductor region is a doped region of a second type;
the semiconductor material of the substrate comprises silicon, the doped region of a first type is a p-doped region, the doped region of a second type is a n-doped region, the p- and n-doped regions are separated by an intrinsic semiconductor region, and the p-doped region, the intrinsic semiconductor region and the n-doped region form a p-i-n photodetector capable of converting an optical signal from an optical fiber placed in the groove to an electric signal;
the monolithic semiconductor photo-coupler device further comprises a first electrode applied to the substrate in contact with the first semiconductor region, and a second electrode applied to the substrate in contact with the second semiconductor region;
the face of the substrate in which the groove is made is planar, the wall further comprises a top edge surface coplanar with the said one planar face of the substrate, and the first and second electrodes are applied to both the top edge surface of the wall and the said one planar face of the substrate; and
the groove is a V-shaped groove, the V-shaped groove extends on both sides of the wall, and the first and second opposite faces of the wall are triangular.

The present invention further relates to a method of fabricating a monolithic photo-coupler device from a substrate of semiconductor material, comprising:
making in one face of the substrate a groove to receive and align an optical fiber;
forming in the semiconductor material of the substrate a wall of given thickness in the prolongation of the groove and transversally to this groove, that wall comprising: on the side of the groove, a first face generally perpendicular to the groove; and a second face opposite to the first face; and
producing first and second semiconductor regions of different electrical properties in the semiconductor material on the first and second faces of the wall, respectively.

According to advantageous embodiments of the fabrication method:
the semiconductor material comprises silicon;
production of the first and second semiconductor regions comprises doping the semiconductor material on the first face of the wall to produce a doped region of a first type, for example a p-doped region, doping the semiconductor material on the second face of the wall to produce a doped region of a second type, for example a n-doped region, separating the p- and n-doped regions by an intrinsic semiconductor region, wherein the p-doped region, the intrinsic semiconductor region and the n-doped region form a p-i-n photodetector capable of converting an optical signal from an optical fiber placed in the groove to an electric signal; and
the fabrication method further comprises applying a first electrode to the substrate in contact with the first semiconductor region, and applying a second electrode to the substrate in contact with the second semiconductor region.

Other objects, advantages and features of the present invention will become more apparent upon reading of the following non-restrictive description of a preferred embodiment thereof, given by way of example only with reference to the accompanying drawings.

### BRIEF DESCRIPTION OF THE DRAWINGS

In the appended drawings:

FIG. 1 is a perspective view of a preferred embodiment of the monolithic semiconductor photo-coupler device according to the present invention; and

FIG. 2 is a side elevational, cross sectional view, taken along line 2-2 of FIG. 1, of the monolithic semiconductor photo-coupler device of FIG. 1.

### DETAILED DESCRIPTION OF THE PREFERRED EMBODIMENT

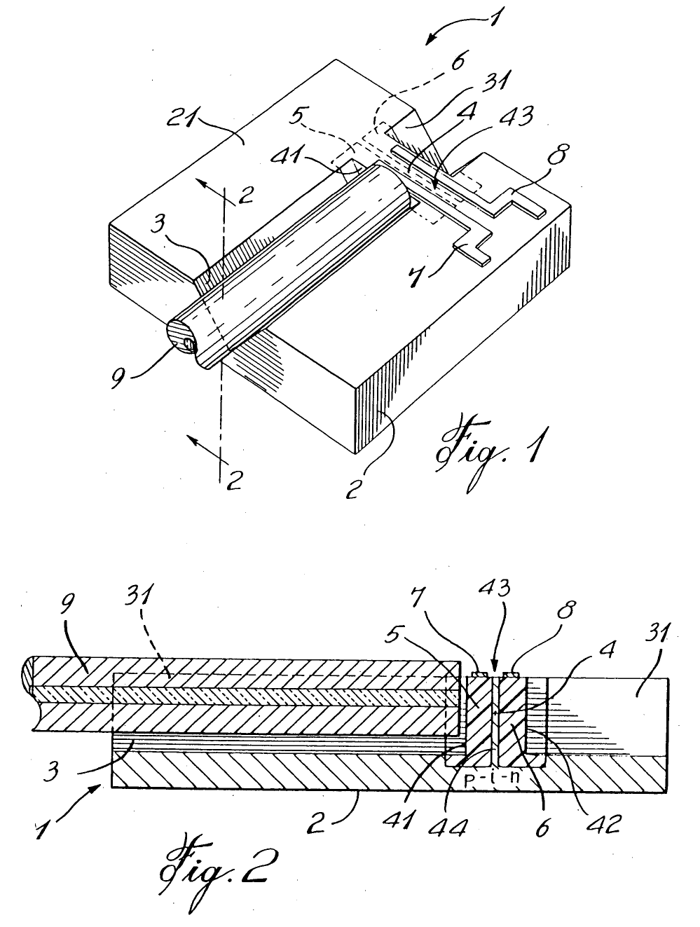

A preferred embodiment of the monolithic semiconductor photo-coupler device according to the present invention will now be described. In the appended drawings, the monolithic semiconductor photo-coupler device is generally identified by the reference 1. Also, identical elements are identified by the same references in both FIGS. 1 and 2 of the drawings.

The preferred embodiment of the monolithic semiconductor photo-coupler device 1 mainly comprises, as shown in FIGS. 1 and 2, a substrate 2, a groove 3, a wall 4, first 5 and second 6 semiconductor regions, a first electrode 7 and a second electrode 8.

The substrate 2 is made of semiconductor material. In the preferred embodiment, silicon is used as semiconductor material. Of course, it is within the scope of the present invention to use other types of semiconductor materials, such as GaAs.

The groove 3 is made in a generally planar face 21 of the substrate 2 to receive an end section of a single-mode or multi-mode optical fiber 9. As illustrated in FIGS. 1 and 2, the groove 3 is preferably V-shaped in cross section. Of course, it is within the scope of the present invention to implement a groove with any other cross section shape. The V-shaped cross section of the groove 3 has the property of positioning the optical fiber 9 in precise alignment with the photodetector or other photo-component which will be described in the following description.

As a non limitative example, the V-shaped groove 3 can be fabricated with high precision in the face 21 of the silicon substrate 2 by photographic masking and etching. Of course, it is within the scope of the present invention to use other methods for making this groove 8 in the face 21.

Although this forms no part of the present invention, just a word to mention that the end section of optical fiber 9 can be bonded to the silicon of the substrate 2 by means of an adhesive such as epoxy. This is only a non limitative example and the present invention is intended to encompass the use of other methods to bond the optical fiber 9 in the V-shaped groove 3.

The wall 4 has a given thickness and is formed in the silicon of the substrate 2 in the prolongation of the groove 3 and transversally to that groove 3. As illustrated in both FIGS. 1 and 2, the wall 4 is formed by making both the V-shaped groove 3 and a V-shaped groove section 31 coaxial with the groove 3 on the side of the wall 4 opposite to groove 3. This forms a wall 4 having:
on the side of the groove 3, a first triangular face 41 generally perpendicular to V-shaped groove 3;
on the side of the V-shaped groove section 31, a second triangular face 42 opposite to the first triangular face 41; and
a generally planar top edge surface 43 coplanar with the generally planar face 21 of the substrate 2 in which the groove 3 is made.

The first 5 and second 6 semiconductor regions have different electrical properties and are produced in the silicon material on the first 41 and second 42 faces of the wall 4, respectively. More specifically:
the silicon material is doped on the first face 41 of the wall 4 to produce a doped region of a first type, for example a p-doped region 5;
the silicon material on the second face 42 of the wall 4 is doped to produce a doped region of a second type, for example a n-doped region 6; and
the p- and n-doped regions 5 and 6 are separated by an intrinsic silicon region 44 (shown in FIG. 2).

In this manner, the p-doped region 5, the intrinsic silicon region 44 and the n-doped region 6 form a p-i-n photodetector capable of converting an optical signal from optical fiber 9 placed in the groove 3 to an electric signal. Instead of a photodetector, the faces 41 and 42 can be doped to produce other types of photo-components such as, for example, a photoemitter component capable of emitting light in the optical fiber 9 for propagation and transmission through this optical fiber 9.

A first electrode 7 is applied to the substrate 2 in contact with the p-doped region 5, while a second electrode 8 is applied to the substrate 2 in contact with the n-doped region 6. Those of ordinary skill in the art will appreciate that the electrodes 7 and 8 can be made of different types of metal and applied by means of conventional techniques used in the field of microelectronics.

As better shown in FIG. 1, the first and second electrodes 7 and 8 are applied on both the top planar edge surface 43 of the wall 4 and on the planar face 21 of the substrate 2 for connection to other circuits (not shown), integrated or not.

FIGS. 1 and 2 clearly show that mounting of the end section of the optical fiber 9 in the groove 3 automatically positions this optical fiber 9 in direct alignment with the photodetector including the p-doped region 5, the intrinsic silicon region 44 and the n-doped region 6.

Those of ordinary skill in the art will also appreciate that the structure of the groove 3 and wall 4 assembly and the fabrication of an photo-component by simply doping the opposite faces of the wall 4 result in a very simple, easily manufactured structure for the monolithic semiconductor photo-coupler device 1.

Although the present invention has been described hereinabove by way of a preferred embodiment thereof, this embodiment can be modified at will, within the scope of the appended claims, without departing from the spirit and nature of the subject invention.

1. A monolithic semiconductor photo-coupler device, comprising:
a substrate made of semiconductor material;
a groove made in one face of the substrate to receive and align an optical fiber;
a wall of given thickness formed in the semiconductor material of the substrate in the prolongation of the groove and transversally to said groove, said wall having:
on the side of the groove, a first face generally perpendicular to the groove; and
a second face opposite to the first face; and
first and second semiconductor regions of different electrical properties formed in the semiconductor material on the first and second faces of the wall, respectively.

2. A monolithic semiconductor photo-coupler device as recited in claim 1, wherein the first semiconductor region is a doped region of a first type, and the second semiconductor region is a doped region of a second type.

3. A monolithic semiconductor photo-coupler device as recited in claim 2, wherein:
the semiconductor material of the substrate comprises silicon;
the doped region of a first type is a p-doped region;
the doped region of a second type is a n-doped region;
the p- and n-doped regions are separated by an intrinsic semiconductor region; and
the p-doped region, the intrinsic semiconductor region and the n-doped region form a p-i-n photodetector capable of converting an optical signal from an optical fiber placed in the groove to an electric signal.

4. A monolithic semiconductor photo-coupler device as recited in claim 1, further comprising:
a first electrode applied to the substrate in contact with the first semiconductor region; and
a second electrode applied to said substrate in contact with the second semiconductor region.

5. A monolithic semiconductor photo-coupler device as recited in claim 4, wherein:
said one face of the substrate in which the groove is made is planar;
the wall further comprises a top edge surface coplanar with said one planar face of the substrate; and
the first and second electrodes are applied to both said top edge surface of the wall and said one planar face of the substrate.

6. A monolithic semiconductor photo-coupler device as recited in claim 1, 2, 3, 4 or 5, wherein the groove is a V-shaped groove.

7. A monolithic semiconductor photo-coupler device as recited in claim 6, wherein the V-shaped groove extends on both sides of the wall, and wherein the first and second opposite faces of the wall are triangular.

8. A method of fabricating a monolithic photo-coupler device from a substrate of semiconductor material, comprising:
making in one face of the substrate a groove to receive and align an optical fiber;
forming in the semiconductor material of the substrate a wall of given thickness in the prolongation of the groove and transversally to said groove, said wall comprising: on the side of the groove, a first face generally perpendicular to the groove; and a second face opposite to the first face; and
producing first and second semiconductor regions of different electrical properties in the semiconductor material on the first and second faces of the wall, respectively.

9. The fabrication method of claim 8, wherein production of the first and second semiconductor regions comprises:
doping the semiconductor material on the first face of the wall to produce a doped region of a first type; and
doping the semiconductor material on the second face of the wall to produce a doped region of a second type.

10. The fabrication method of claim 8, wherein the semiconductor material of the substrate comprises silicon and wherein production of the first and second semiconductor regions comprises:
doping the semiconductor material on the first face of the wall to produce a p-doped region;
doping the semiconductor material on the second face of the wall to produce a n-doped region; and
separating the p- and n-doped regions by an intrinsic semiconductor region; and
wherein the p-doped region, the intrinsic semiconductor region and the n-doped region form a p-i-n photodetector capable of converting an optical signal from an optical fiber placed in the groove to an electric signal.

11. The fabrication method of claim 8, further comprising:
applying a first electrode to the substrate in contact with the first semiconductor region; and
applying a second electrode to said substrate in contact with the second semiconductor region.
